(19) United States
(12) Patent Application Publication
(10) Pub. No.: US 2011/0277386 A1
(43) Pub. Date: Nov. 17, 2011

(54) Tri-vent awning window

(76) Inventor: Robert L. Nevins, Boiceville, NY (US)

(21) Appl. No.: 13/136,054

(22) Filed: Jul. 21, 2011

Related U.S. Application Data
(63) Continuation-in-part of application No. 11/811,812, filed on Jun. 12, 2007, now Pat. No. 7,650,721.

(51) Int. Cl. E06B 7/08; E06B 9/52; H01L 31/048; E06B 7/28

(52) U.S. Cl. 49/58; 49/71; 49/70

(57) ABSTRACT

A tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming. The tri-vent awning window includes a frame, an inner pane, an outer pane, and a heat sink. The inner pane is replaceably mounted to the frame so as to form a first vent. The outer pane is pivotally mounted to the frame so as to form a second vent, and is spaced from the inner pane so as to form a space therebetween. The heat sink is removably mounted to the frame, in the space, and when removed, creates a passive solar application. The inner pane has an in-place position and the outer pane has an open position during which in the warm weather the sunlight heat hits the heat sink and passes therethrough and rises by convection. The inner pane has a removed position and the outer pane has a closed position during which in the cold weather the interior sunlight heat is circulated from the space.

### 1. CROSS REFERENCE TO RELATED APPLICATIONS

The instant patent application is a Continuation-In-Part application of patent application Ser. No. 11/811,812, filed Jun. 12, 2007, for a WINDOW FOR ABSORBING SUNLIGHT HEAT IN WARM WEATHER THAT OTHERWISE WOULD FLOW UNCONTROLLED THERETHROUGH AND DISCHARGING THE SUNLIGHT HEAT TO THE ATMOSPHERE WHILE PERMITTING RELATIVELY UNOBSTRUCTED VISION THERETHROUGH AND PASSING THE SUNLIGHT HEAT IN COLD WEATHER THERETHROUGH FOR THERMAL WARMING, and incorporated herein by reference thereto.

### 2. BACKGROUND OF THE INVENTION

A. Field of the Invention

The embodiments of the present invention relate to an awning window, and more particularly, the embodiments of the present invention relate to a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming.

B. Description of the Prior Art

Window, door lights, and similar transparent structures probably represent the single greatest source of heat loss in cold weather and heat gain in warm weather in most buildings. Recognition of this fact has led to a number of widely accepted developments of which the passive “storm” window and the “thermal pane” insulating window are typical.

Although these devices are often quite effective in attenuating heat flow, nevertheless, they fail to achieve truly optimum performance because they act only as heat barriers. Thus, these structures fail to provide some way to utilize or take full advantage of the radiant solar heat energy that is incident upon the window or door light in question.

As heating and air conditioning costs increase, and as the fuels that are needed to provide this heating and air conditioning become more scarce, there is an unquestionable need to improve conservation and heat utilization technology.

Numerous innovations for windows and window-related devices have been provided in the prior art, which will be described below in chronological order to show advancement in the art, and which are incorporated herein by reference thereto. Even though these innovations may be suitable for the specific individual purposes to which they address, nevertheless, they each differ in structure, and/or operation, and/or purpose, from the embodiments of the present invention in that they do not teach a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming.

(1) U.S. Pat. No. 4,296,734 to Nevins.

U.S. Pat. No. 4,296,734—issued to Nevins on Oct. 27, 1981 in U.S. class 126 and subclass 431—teaches a heat sink in the form of a mesh interposed between two spaced panes in a window or door light. A combination of holes and passageways formed in the window sash frame members permit the selective establishment of convective air currents past the mesh to absorb the solar-converted thermal-heat stored in the sink. By manipulating the source of the air for these convective currents, i.e., from the inside or the outside of a building, and by choosing the volume into which the warmed air currents are to be discharged, i.e., inside or outside the building, significant heating and cooling efficiencies are achieved.

(2) U.S. Pat. No. 4,365,620 to Bliamptis.

U.S. Pat. No. 4,365,620—issued to Bliamptis on Dec. 28, 1982 in U.S. class 126 and subclass 429—teaches a reversible, variably inclinable window with controlled convection for mounting in a window casing in a building for solar heating and cooling, which includes a window frame having top and bottom portions and being adapted to pivot about a horizontal axis intermediate the portions, a first window panel mounted in the frame capable of transmitting both visible and infrared radiation, a second window panel mounted in the frame and substantially parallel and in a spaced relationship to the first window panel and being capable of transmitting visible radiation and blocking infrared radiation, and openings proximate to the top and bottom portions for providing air passageways to a space between the first and second window panels so that rotation of the assembly about its horizontal axis can place either of the panels toward the outside of the building for selective reflection or absorbtion of the radiant energy to enable heating or cooling of the interior space between the panels in order to utilize the properties of the air caused to pass therethrough. Sealing apparatus at the sides of the window casing seal against the window frame, while allowing for optimization of the inclination angle of the window with respect to radiant energy impinging thereon.

(3) U.S. Pat. No. 4,382,436 to Hager.

U.S. Pat. No. 4,382,436—issued to Hager on May 10, 1983 in U.S. class 126 and subclass 429—teaches a window assembly. The window assembly includes first and second transparent sheets, with an open volume between the sheets. A selective light-reflecting device is disposed in the open volume allowing passage of light from one sheet to the other in cold weather, but preventing passage in warm weather. A vent in a first frame mounting the first sheet selectively allows the passage of air from the exterior of a building containing the window assembly to the volume between the reflecting device and the first sheet. The air is circulated and then passed back to the exterior of the building. Another vent in a second frame mounting the second sheet allows circulation of air from the interior of the building to between the transparent sheets and back to the building interior.

(4) U.S. Pat. No. 4,577,619 to Howe Jr.

U.S. Pat. No. 4,577,619—issued to Howe Jr. on Mar. 25, 1986 in U.S. class 126 and subclass 431—teaches window and skylight assemblies having self-contained ventilating systems. Two sheets of a transparent or translucent material are spaced-apart in parallel relationship so as to form an air flow channel between the sheets. An adjustable shade is positioned in the air flow channel to regulate the amount of sunlight passing through the window and skylight assemblies. A fan in the top or bottom of the assembly causes air to be drawn into the assembly and passed through the air flow channel where it absorbs heat from the shade and sides of the assembly. This air is then directed into the building to provide heat or is vented to the outside to decrease the heat gain in the building.

(5) U.S. Pat. No. 5,063,984 to Cherveny.

U.S. Pat. No. 5,063,984—issued to Cherveny on Nov. 12, 1991 in U.S. class 160 and subclass 7—teaches a solar heating device. A support structure rests on the window sill, and suspends two thermistors. One thermistor is supported on the room side of drapery and the other thermistor is supported between the drapery and a window. When the net heat flow is inward from outside the room, the thermistor near the window will be warmer than the room side thermistor. When this occurs, the temperature-dependent resistances of thermistors, voltage divider resistances, and a comparator turn on a light-emitting diode. This indicates that the drapery should be opened to let solar radiation in to heat the room. Otherwise, the drapery should be closed to conserve the existing heat in the room.

(6) U.S. Pat. No. 5,090,302 to Eisenbeisz.

U.S. Pat. No. 5,090,302—issued to Eisenbeisz on Feb. 25, 1992 in U.S. class 454 and subclass 205—teaches a window for reducing heat gain or loss through windows by ventilating interior air at interior temperatures over the exterior of the window in a controlled circulation pattern using nozzle tubes with a plurality of transversely disposed air-jet apertures mounted in the jambs and mullions. Interior air is ventilated by a fan or compressor into air supply tubing that is attached to the nozzle tubes. Preferably, the amount of air ventilated is less than or equal to the minimum amount of ventilation required under ventilation standards.

### (7) United States Patent Application Publication Number 2003/0168056 to Fidler.

United States Patent Application Publication Number 2003/0168056—published to Fidler on Sep. 11, 2003 in U.S. class 126 and subclass 628—teaches a Venetian-blind-type solar heater. The top outer half of the slats are coated with a heat-absorbing material, while the rest of the slats are coated with a non-heat-absorbing material. Thermal conduction in the metal slats heats the entire slat. The distance between the slats are half the width of the slat so that the slats overlap. The number of slats increases, thereby increasing the total surface area available for heat transfer to the inside room air by convection and thermal radiation. When the orientation of the slats are reversed, the heat-absorbing surface area is shielded from outside solar radiation and any stray inside room radiation.

### (8) United States Patent Application Publication Number 2005/0056272 to Durbin.

United States Patent Application Publication Number 2005/0056272—published to Durbin on Mar. 17, 2005 in U.S. class 126 and subclass 628—teaches a portable solar heater for use with a window of an enclosed space of a building structure or vehicle. The portable solar heater includes a sheet metal body and a releasable support to mount the sheet metal body relative to an interior surface of the window. The sheet metal body includes a pair of oppositely facing surfaces separated by a thickness “t” of the sheet metal. One of the surfaces is a window-facing surface and is a highly solar-energy-absorptive surface.

### (9) United States Patent Application Publication Number 20070289231 to the Instant Inventor Nevins.

United States Patent Application Publication Number 20070289231—published to the instant inventor Nevins on Dec. 20, 2007 in U.S. class 52 and subclass 204.5—teaches a window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming. The window includes a frame, an inner pane, an outer pane, and a heat sink. The inner pane is pivotally mounted to the frame so as to form a first vent. The outer pane is pivotally mounted to the frame and spaced from the inner pane so as to form a space therebetween. The heat sink is rotatably mounted to the frame, and has an extended position in which the heat sink occupies coextensively the space for absorbing the sunlight heat in the warm weather that otherwise would flow uncontrolled therethrough and discharging the sunlight heat to the atmosphere while permitting relatively unobstructed vision therethrough, and a retracted position in which the heat sink does not occupy coextensively the space for passing the sunlight heat in the cold weather therethrough for thermal warming.

It is apparent that numerous innovations for windows and window-related devices have been provided in the prior art, which are adapted to be used. Furthermore, even though these innovations may be suitable for the specific individual purposes to which they address, they would not be suitable for the purposes of the embodiments of the present invention as heretofore described, namely, a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming.

### 3. SUMMARY OF THE INVENTION

Thus, an object of the embodiments of the present invention is to provide a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming, which avoids the disadvantages of the prior art.

Briefly stated, another object of the embodiments of the present invention is to provide a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming. The window includes a frame, an inner pane, an outer pane, and a heat sink. The inner pane is replaceably mounted to the frame so as to form a first vent. The outer pane is pivotally mounted to the frame so as to form a second vent, and is spaced from the inner pane so as to form a space therebetween. The heat sink is removably mounted to the frame, in the space, and when removed, creates a passive solar application. The inner pane has an in-place position and the outer pane has an open position during which in the warm weather the sunlight heat hits the heat sink and passes therethrough and rises by convection. The inner pane has a removed position and the outer pane has a closed position during which in the cold weather the interior sunlight heat is circulated from the space.

The novel features considered characteristic of the embodiments of the present invention are set forth in the appended claims. The embodiments of the present invention themselves, however, both as to their construction and to their method of operation together with additional objects and advantages thereof will be best understood from the following description of the specific embodiments when read and understood in connection with the accompanying figures of the drawing.

### 4. BRIEF DESCRIPTION OF THE FIGURES OF THE DRAWING

The figures of the drawing are briefly described as follows:

FIG. 1 is a diagrammatic exterior elevational view of the tri-vent awning window of the embodiments of the present invention absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming;

FIG. 2 is a diagrammatic interior elevational view of the tri-vent awning window of the embodiments of the present invention absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming;

FIG. 3 is an enlarged diagrammatic cross sectional view taken along LINE 3-3 in FIGS. 1 and 2 of the tri-vent awning window of the embodiments of the present invention in the warm weather mode;

FIG. 4 is an enlarged diagrammatic cross sectional view taken along LINE 4-4 in FIGS. 1 and 2 of the tri-vent awning window of the embodiments of the present invention in the cold weather mode; and

FIG. 5 is an enlarged diagrammatic perspective view of the vent assembly of the tri-vent awning window of the embodiments of the present invention identified by ARROW 5 in FIGS. 1-4.

### 5. LIST OF REFERENCE NUMERALS UTILIZED IN THE FIGURES OF THE DRAWING

### A. General.

10 tri-vent awning window of embodiments of present invention for absorbing sunlight heat 12 in warm weather that otherwise would flow uncontrolled therethrough and discharging sunlight heat 12 to atmosphere 14 while permitting relatively unobstructed vision therethrough and passing sunlight heat 12 in cold weather therethrough for thermal warming
12 sunlight heat
14 atmosphere

### B. Overall Configuration of Tri-Vent Awning Window 10.

16 frame
24 inner pane
26 outer pane
28 heat sink
32 space

### C. Specific Configuration of Frame 16.

40 pair of side jambs of frame 16
42 upper cross member of frame 16
46 lower cross member of frame 16

### D. Specific Configuration of Inner Pane 24.

78 inner frame of inner pane 24
79 hinges of inner pane 24
80 inner lite of inner pane 24

### E. Specific Configuration of Outer Pane 26.

81 crank of outer pane 26
81a weather-proof hinges of outer pane 26

### F. Specific Configuration of Heat Sink 28.

82 solar-energy conversion screen of heat sink 28

### G. Specific Configuration of Vent Assembly 84.

84 vent assembly
86 plurality of through bores through upper cross member 42 of frame 16 of vent assembly 84
88 pair of channels of vent assembly 84
90 slider of vent assembly 84
92 plurality of through bores through slider 90 of vent assembly 84

### 6. DETAILED DESCRIPTION OF THE PREFERRED EMBODIMENTS

### A. General.

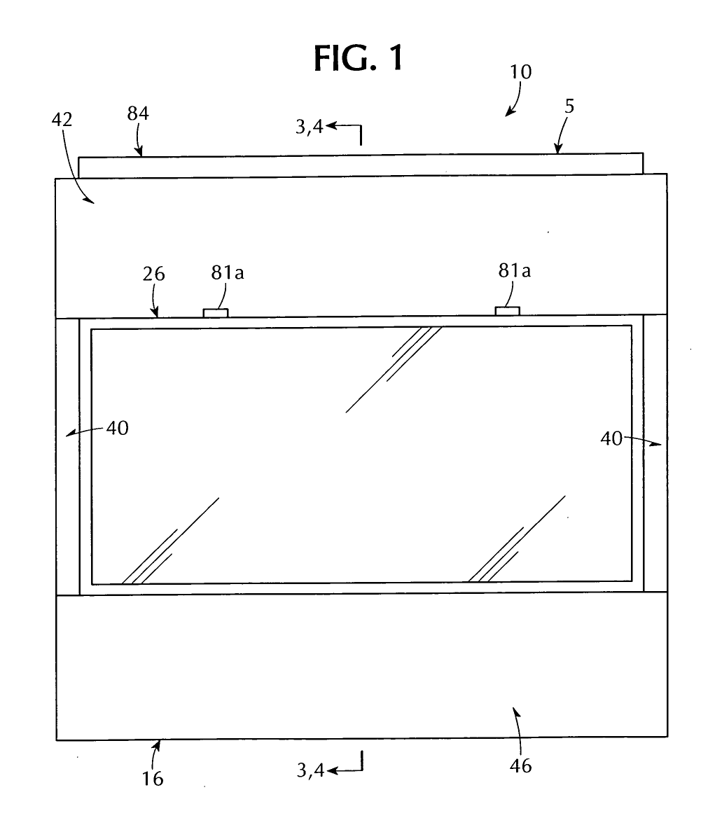

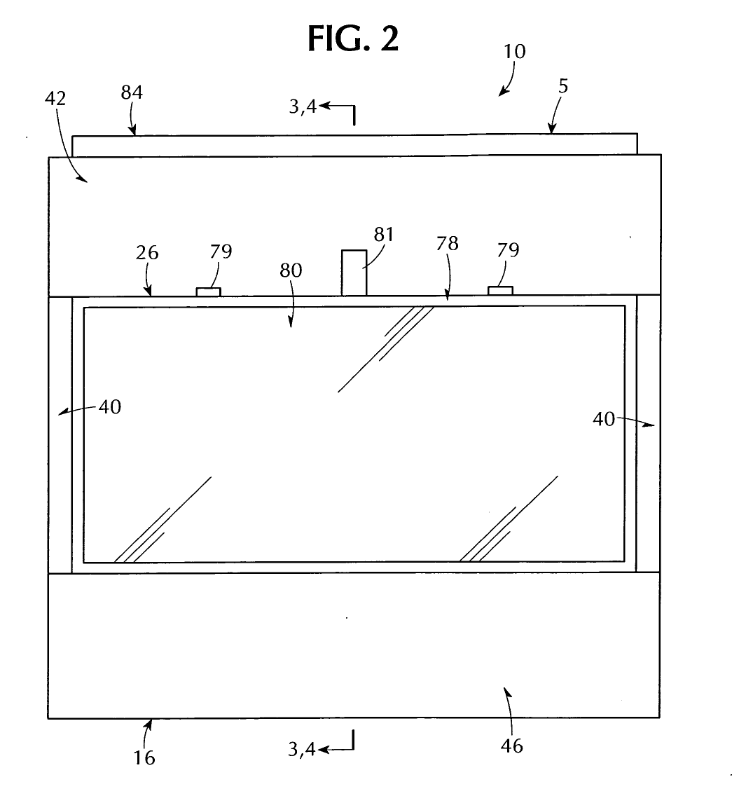

Referring now to the figures, in which like numerals indicate like parts, and particularly to FIGS. 1-4, which are, respectively, a diagrammatic exterior elevational view of the tri-vent awning window of the embodiments of the present invention absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming, a diagrammatic interior elevational view of the tri-vent awning window of the embodiments of the present invention absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming, a diagrammatic cross sectional view taken along LINE 3-3 in FIGS. 1 and 2 of the tri-vent awning window of the embodiments of the present invention in the warm weather mode, and a diagrammatic cross sectional view taken along LINE 4-4 in FIGS. 1 and 2 of the tri-vent awning window of the embodiments of the present invention in the cold weather mode, the tri-vent awning window of the embodiments of the present invention is shown generally at 10 for absorbing sunlight heat 12 in warm weather that otherwise would flow uncontrolled therethrough and discharging the sunlight heat 12 to the atmosphere 14 while permitting relatively unobstructed vision therethrough and passing the sunlight heat 12 in cold weather therethrough for thermal warming.

### B. Overall Configuration of the Tri-Vent Awning Window 10.

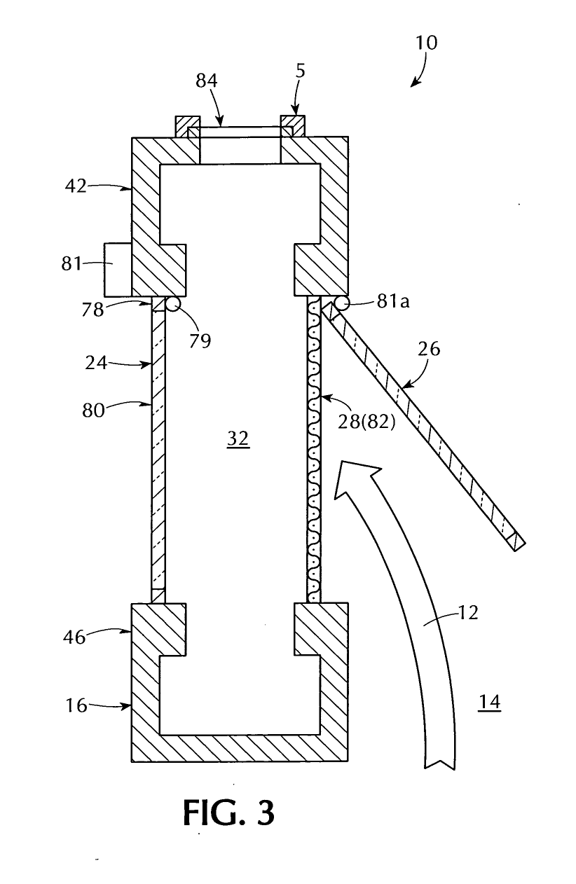

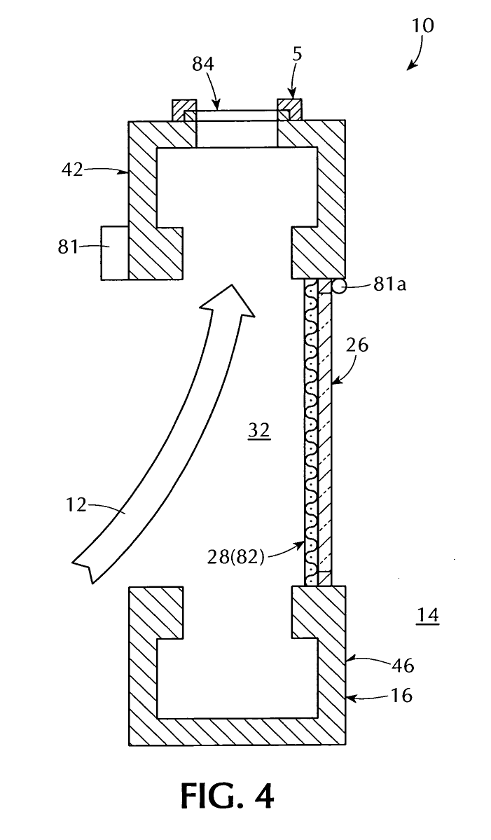

The tri-vent awning window comprises a frame 16, an inner pane 24, an outer pane 26, and a heat sink 28. The inner pane 24 is either replaceably or hingedly mounted to the frame 16 so as to form a first vent. The outer pane 26 is pivotally mounted to the frame 16 so as to form a second vent, and spaced from the inner pane 24 so as to form a space 32 therebetween. The heat sink 28 is removably mounted to the frame 16, in the space 32, and when removed, creates a passive solar application. The inner pane 24 has an in-place position and the outer pane 26 has an open position during which—in the warm weather—the sunlight heat 12 hits the heat sink 28 and passes therethrough and rises by convection (FIG. 3). The inner pane 24 has a removed position and the outer pane 26 has a closed position during which—in the cold weather—the interior sunlight heat 12 is circulated from the space 32 (FIG. 4).

### C. Specific Configuration of the Frame 16.

The frame 16 is made of a material selected from the group consisting of wood, fiberglass, vinyl, metal, and combinations thereof.

The frame 16 has a pair of side jambs 40, an upper cross member 42 extending horizontally across the pair of side jambs 40 of the frame 16, and a lower cross member 46 extending horizontally across the pair of side jambs 40.

### D. Specific Configuration of the Inner Pane 24.

As shown in FIGS. 2 and 3, the inner pane 24 comprises an inner frame 78 and an inner lite 80. The inner frame 78 of the inner pane 24 is either replaceably attached to the frame 16 or hingedly attached by hinges 79 to the frame 16, and is hand-operated. The inner lite 80 of the inner pane 24 is contained within the inner frame 78 of the inner pane 24. The pair of side jambs 40 of the frame 16, the upper cross member 42 of the frame 16, and the lower cross member 46 of the frame 16 accommodate the inner frame 78 of the inner pane 24, and are rabetted to facilitate the accommodation.

The inner lite 80 of the inner pane 24 is single glazed, and is made of a transparent material selected from the group consisting of plastic, plexiglass, and glass. The inner frame 78 of the inner pane 24 is made of a material selected from the group consisting of wood, fiberglass, vinyl, metal, and combinations thereof.

### E. Specific Configuration of the Outer Pane 26.

The outer pane 26 is pivotally mounted to the upper cross member 42 of the frame 16 by weather-proof hinges 81a and depends therefrom for shedding rain and snow so as to prevent the rain and the snow from entering when the outer pane 26 is opened, is pivoted either by a crank 81 or by hand, and is interchangeable between either a double glazed or a photovoltaic panel.

When the outer panel 26 is a photovoltaic panel, the outer panel 26 is pivoted to a high position in the summer so as to optimize summer sun that is very high in the summer sky, or to a low or closed position in the winter so as to optimize winter sun that is very low in the winter sky, or to any position therebetween as there is transition between seasons so as to optimize sun.

### F. Specific Configuration of the Heat Sink 28.

As shown in FIGS. 3 and 4, the heat sink 28 comprises a solar-energy conversion screen 82. The solar-energy conversion screen 82 of the heat sink 28 has sides, and is fixedly attached to the pair of side jambs 40 of the frame 16, the upper cross member 42 of the frame 16, and the lower cross member 46 of the frame 16 for preventing any of the sunlight heat 12 from getting around the sides of the solar-energy conversion screen 82 of the heat sink 28, extends through the space 32, and is disposed just inward of the outer pane 26.

The solar-energy conversion screen 82 of the heat sink 28 is made of a thin, pliable, dark fiberglass fabric mesh for preventing infiltration of insects therethrough, and is interchangeable with a foiled-faced heat-reflecting shade or an insulated shade for enhancing R value of the tri-vent awning window 10.

As shown in FIGS. 1-4, the tri-vent awning window 10 further comprises a vent assembly 84 so as to form a third vent.

### G. Specific Configuration of the Vent Assembly 84.

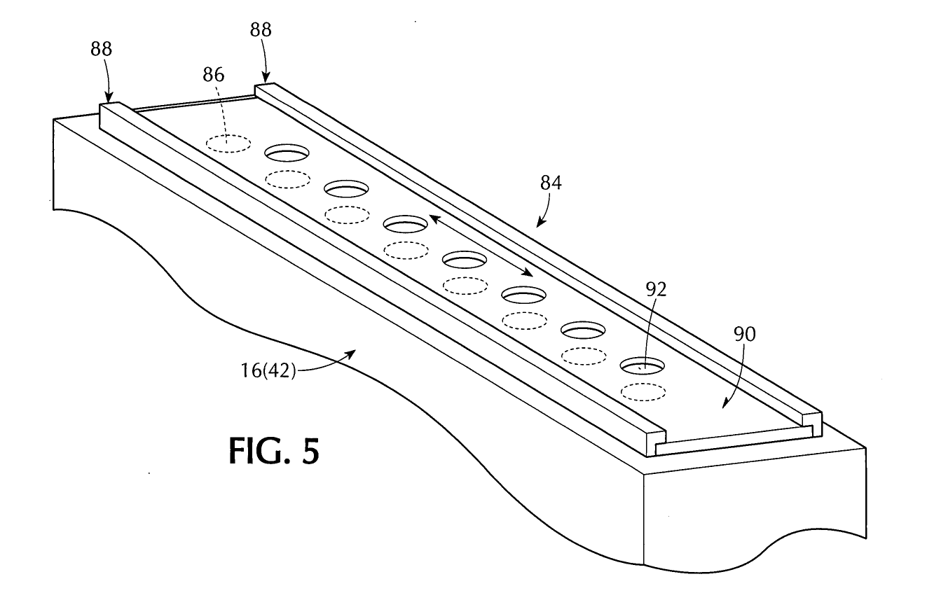

The specific configuration of the vent assembly 84 can best be seen in FIG. 5, which is an enlarged diagrammatic perspective view of the vent assembly of the tri-vent awning window of the embodiments of the present invention identified by ARROW 5 in FIGS. 1-4, and as such, will be discussed with reference thereto.

The vent assembly 84 comprises the upper cross member 42 of the frame 16 having a plurality of through bores 86 with diameters. The plurality of through bores 86 through the upper cross member 42 of the frame 16 are vertically disposed and spaced-apart from each other a distance equal to slightly more than their diameters.

The vent assembly 84 further comprises a pair of channels 88. The pair of channels 88 of the vent assembly 84 extend along the upper cross member 42 of the frame 16, straddling the plurality of through bores 86 through the upper cross member 42 of the frame 16, and are made of a material selected from the group consisting of wood, fiberglass, vinyl, metal, and combinations thereof.

The vent assembly 84 further comprises a slider 90. The slider 90 of the vent assembly 84 has a plurality of through bores 92 with diameters that equal the diameters of the plurality of through bores 86 through the upper cross member 42 of the frame 16, and is made of a flat slat material selected from the group consisting of wood, fiberglass, vinyl, metal, and combinations thereof. The plurality of through bores 92 through the slider 90 of the vent assembly 84 are vertically disposed and spaced-apart from each other a distance equal to their diameters.

The slider 90 of the vent assembly 84 slides back and forth in the pair of channels 88 of the vent assembly 84, and when the plurality of through bores 92 through the slider 90 of the vent assembly 84 align with the plurality of through bores 86 through the upper cross member 42 of the frame 16, air is permitted to flow upwardly therethrough, but when the plurality of through bores 92 through the slider 90 of the vent assembly 84 do not align with the plurality of through bores 86 through the upper cross member 42 of the frame 16, air is prevented from flowing upwardly therethrough.

The slider 90 of the vent assembly 84 has a length to prevent it from sticking out past the pair of side jambs 40 of the frame 16 when it is slid back and forth.

### H. Impressions.

It will be understood that each of the elements described above, or two or more together, may also find a useful application in—other types of constructions differing from the types described above.

While the embodiments of the present invention have been illustrated and described as embodied in a tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming, however, they are not limited to the details shown, since it will be understood that various omissions, modifications, substitutions, and changes in the forms and details of the embodiments of the present invention illustrated and their operation can be made by those skilled in the art without departing in any way from the spirit of the embodiments of the present invention.

Without further analysis, the foregoing will so fully reveal the gist of the embodiments of the present invention that others can by applying current knowledge readily adapt them for various applications without omitting features that from the standpoint of the prior art fairly constitute characteristics of the generic or specific aspects of the embodiments of the present invention.

The invention claimed is:

1. A tri-vent awning window for absorbing sunlight heat in warm weather that otherwise would flow uncontrolled therethrough and discharging the sunlight heat to the atmosphere while permitting relatively unobstructed vision therethrough and passing the sunlight heat in cold weather therethrough for thermal warming, comprising:
a) a frame;
b) an inner pane;
c) an outer pane; and
d) a heat sink;
wherein said inner pane is either replaceably or hingedly mounted to said frame so as to form a first vent;
wherein said outer pane is pivotally mounted to said frame so as to form a second vent;
wherein said outer pane is spaced from said inner pane so as to form a space therebetween;
wherein said heat sink is removably mounted to said frame, in said space, and when removed, creates a passive solar application;
wherein said inner pane has an in-place position and said outer pane has an open position during which, in the warm weather, the sunlight heat hits said heat sink and passes therethrough and rises by convection; and
wherein said inner pane has a removed position and said outer pane has a closed position during which, in the cold weather, interior sunlight heat is circulated from said space.

2. The window of claim 1, wherein said frame is made of a material selected from the group consisting of wood, fiberglass, vinyl, metal, and combinations thereof.

3. The window of claim 1, wherein said frame has:
a) a pair of side jambs;
b) an upper cross member extending horizontally across said pair of side jambs of said frame; and
c) a lower cross member extending horizontally across said pair of side jambs of said frame.

4. The window of claim 3, wherein said inner pane comprises:
a) an inner frame; and
b) an inner lite.

5. The window of claim 4, wherein said inner frame of said inner pane is either replaceably attached to said frame or hingedly attached by hinges to said frame;
wherein said inner frame of said inner pane is hand-operated;
wherein said inner lite of said inner pane is contained within said inner frame of said inner pane; and
wherein said pair of side jambs of said frame, said upper cross member of said frame, and said lower cross member of said frame accommodate said inner frame of said inner pane.

6. The window of claim 5, wherein said pair of side jambs of said frame, said upper cross member of said frame, and said lower cross member of said frame are rabetted to facilitate accommodation of said inner frame of said inner pane.

7. The window of claim 4, wherein said inner lite of said inner pane is single glazed;
wherein said inner lite of said inner pane is made of a transparent material selected from the group consisting of plastic, plexiglass, and glass; and
wherein said inner frame of said inner pane is made of a material selected from the group consisting of wood, fiberglass, vinyl, metal, and combinations thereof.

8. The window of claim 3, wherein said outer pane is pivotally mounted to said upper cross member of said frame by weather-proof hinges and depends therefrom for shedding rain and snow so as to prevent the rain and the snow from entering when said outer pane is opened.

9. The window of claim 1, wherein said outer pane is double glazed.

10. The window of claim 3, wherein said heat sink comprises a solar-energy conversion screen.

11. The window of claim 10, wherein said solar-energy conversion screen of said heat sink has sides;
wherein said solar-energy conversion screen of said heat sink is fixedly attached to said pair of side jambs of said frame, said upper cross member of said frame, and said lower cross member of said frame for preventing any of the sunlight heat from getting around said sides of said solar-energy conversion screen of said heat sink;
wherein said solar-energy conversion screen of said heat sink extends through said space; and
wherein said solar-energy conversion screen of said heat sink is disposed just inward of said outer pane.

12. The window of claim 10, wherein said solar-energy conversion screen of said heat sink is made of a thin, pliable, dark fiberglass fabric mesh for preventing infiltration of insects therethrough, and is interchangeable with a foiled-faced heat-reflecting shade or an insulated shade for enhancing R value of said tri-vent awning window.

13. The window of claim 3, further comprising a vent assembly so as to form a third vent.

14. The window of claim 8, wherein said outer pane is pivoted by a crank.

15. The window of claim 13, wherein said vent assembly comprises said upper cross member of said frame having a plurality of through bores with diameters;
wherein said plurality of through bores through said upper cross member of said frame are vertically disposed; and
wherein said plurality of through bores through said upper cross member of said frame are spaced-apart from each other a distance equal to slightly more than their diameters.

16. The window of claim 15, wherein said vent assembly comprises a pair of channels;
wherein said pair of channels of said vent assembly extend along said upper cross member of said frame; and
wherein said pair of channels of said vent assembly straddle said plurality of through bores through said upper cross member of said frame.

17. The window of claim 16, wherein said pair of channels of said vent assembly are made of a material selected from the group consisting of wood, fiberglass, vinyl, metal, and combinations thereof.

18. The window of claim 16, wherein said vent assembly comprises a slider;
wherein said slider of said vent assembly has a plurality of through bores with diameters that equal said diameters of said plurality of through bores through said upper cross member of said frame;
wherein said plurality of through bores through said slider of said vent assembly are vertically disposed; and
wherein said plurality of through bores through said slider of said vent assembly are spaced-apart from each other a distance equal to their diameters.

19. The window of claim 18, wherein said slider of said vent assembly is made of a flat slat material selected from the group consisting of wood, fiberglass, vinyl, metal, and combinations thereof.

20. The window of claim 18, wherein said slider of said vent assembly slides back and forth in said pair of channels of said vent assembly, and when said plurality of through bores through said slider of said vent assembly align with said plurality of through bores through said upper cross of said frame, air is permitted to flow upwardly therethrough, but when said plurality of through bores through said slider of said vent assembly do not align with said plurality of through bores through said upper cross member of said frame, air is prevented from flowing upwardly therethrough.

21. The window of claim 18, wherein said slider of said vent assembly has a length to prevent it from sticking out past said pair of side jambs of said frame when it is slid back and forth.

22. The window of claim 1, wherein said outer pane is a photovoltaic panel.

23. The window of claim 22, wherein said photovoltaic panel of said outer pane is pivoted to a high position in the summer so as to optimize summer sun that is very high in the summer sky;
wherein said photovoltaic panel of said outer pane is pivoted to a low or closed position in the winter so as to optimize winter sun that is very low in the winter sky; and
wherein said photovoltaic panel of said outer pane is pivoted to any position between said high position and said low position as there is transition between seasons so as to optimize sun.
